(19) United States
(12) Patent Application Publication
(10) Pub. No.: US 2023/0246118 A1
(43) Pub. Date: Aug. 3, 2023

(54) METHOD AND SYSTEM FOR THE PRODUCTION OF A STARTING MATERIAL FOR A SILICON SOLAR CELL WITH PASSIVATED CONTACTS

(71) Applicant: SINGULUS TECHNOLOGIES AG, Kahl am Main (DE)

(72) Inventors: Benjamin Mandlmeier, Pöcking (DE); Simon Hübner, Seligenstadt (DE); Peter Wohlfart, Kahl am Main (DE)

(21) Appl. No.: 17/913,088

(22) PCT Filed: Mar. 24, 2021
(86) PCT No.: PCT/EP2021/057582

§ 371 Date: Sep. 20, 2022

(30) Foreign Application Priority Data
Mar. 26, 2020 (DE) 10 2020 001 980.3

(51) Int. Cl. H01L 31/20; H01L 31/18

(52) U.S. Cl. CPC H01L 31/208; H01L 31/206; H01L 31/1868; H01L 31/1864; H01L 31/02245

(57) ABSTRACT

The present invention is directed to a method as well as to a machine for producing a starting material for a silicon solar cell with passivated contacts.

The present invention is directed to a method as well as to a machine for producing a starting material for a silicon solar cell with passivated contacts.

Crystalline silicon solar cells with so-called “passivated contacts” require the formation of a highly doped polycrystalline silicon layer on a thin oxide layer (the so-called “tunnel oxide layer”) on at least one side of the solar cell. The silicon layer can be deposited in an amorphous state. By means of a subsequent annealing process, the amorphous silicon can be converted into the polycrystalline state. For the functionality of the solar cell, high doping of this silicon layer with an element from the 3rd main group (p-type) or the 5th main group (n-type) is necessary. In addition, for some cell concepts, the aim is also to dope the region of the silicon base material directly below the tunnel oxide layer by means of a stronger diffusion. The so-called front surface field or back surface field achieved thereby additionally reduces the recombination of charge carriers at the silicon-tunnel oxide interface.

So far, it has been necessary to deposit the doped silicon layer, for example, by means of LPCVD (low pressure chemical vapor deposition), in order to produce highly doped passivated contacts. Since LPCVD does not allow substrates to be coated exclusively on one side, the opposite side of the solar cell is thus generally also doped with the wrong polarity. This is undesirable and must either be prevented from the outset by applying a protective mask, or the doping on the front side must be subsequently removed again. The problem of too low doping and the problem of the doping profile not being independently adjustable during the thermal step can be solved by selectively applying the first and second layers on one side using the sputtering process, which can be used on one side, and by selectively adjusting the concentration of the dopant source and the diffusion properties of diffusion barriers.

WO 2018/102852 A1 describes a process for fabricating silicon solar cells in which a doped, amorphous silicon layer is deposited on the oxide-covered silicon substrate by means of so-called cathode sputtering, wherein said silicon layer is subsequently converted into the desired polycrystalline silicon in an annealing process.

Doping an intrinsic amorphous silicon film (a-Si:H) is well known and can be achieved, for example, by sputtering with doped silicon targets, wherein this layer is particularly used for heterojunction solar cells (cf., for example, X. Zhang et al., Characterization of Sputtering Deposited Amorphous Silicon Films for Silicon Heterojunction Solar Cells, 2016 IEEE 43rd Photovoltaic Specialists Conference, Portland, Oreg., 2016, pages 73-76). When the amorphous silicon layer is deposited by sputtering in this way, the dopant concentration of the layer depends on the dopant concentration of the target material. Silicon as a target material is usually produced in a melting metallurgy process and, due to the segregation during the crystallization from the melt, allows only a limited dopant concentration of at most 5×10²⁰ cm⁻³ in the case of boron or of at most 5×10¹⁹ cm⁻³ in the case of phosphorus.

Higher dopant concentrations in sputter layers can be achieved, for example, by co-sputtering silicon and a dopant, as described, for example, in WO 2018/102852 A1. Alternatively, silicon can also be sputtered in an atmosphere containing the dopant as a gas (so-called reactive sputtering). However, both variants are not ideal for an industrial application, in particular for n-doping (phosphorus), since, on the one hand, a highly doped material for co-sputtering phosphorus is missing and, on the other hand, gases containing P or B (monophosphane, diborane) are highly toxic for a reactive process.

It is therefore an object of the present invention to provide a method as well as a machine for producing a starting material for a silicon solar cell with passivated contacts, with which the necessary starting concentration of the dopant can be achieved in a manner that is efficient and suitable for industrial application.

This object is achieved by a method according to claim 1 and a machine according to claim 21.

Accordingly, the present invention is directed to a method for producing a starting material for a silicon solar cell with passivated contacts, in which firstly a silicon wafer with a tunnel oxide layer is provided. Subsequently, the tunnel oxide layer is coated with at least one first layer of amorphous silicon. This coating is preferably carried out by means of cathode sputtering. Subsequently, this first layer of amorphous silicon is coated with at least one second layer comprising a dopant. The application of the second layer is also preferably carried out by means of cathode sputtering. The coated silicon wafer or stack of layers is then annealed at a temperature of at least 700° C.

In other words, the method according to the invention enables the desired high doping via the additional application of a layer containing the dopant in a sufficient concentration. During the subsequent thermal step, which must be used to recrystallize the amorphous silicon layer, the highly concentrated dopant from the dopant layer can diffuse into the first layer of amorphous silicon and/or the underlying interface region of the silicon base material below the tunnel oxide layer. Thus, a sufficiently high p- or n-conductivity is generated there in both regions.

Compared to the post-doping approach (for example with POCl₃) commonly used in the prior art, the method according to the invention has the following advantages:
no toxic process gases
possibility of using a simple furnace
unilateral process
layer deposition, doping and optional annealing in one machine

Hence, with the aid of the well controllable and industrially widespread sputtering process, the invention makes it possible to apply a layer system that is individually adapted to the cell properties and contains sufficient dopant. Thus, in a subsequent annealing step, both the amorphously deposited silicon layer can be converted into the desired polycrystalline state and the dopant profile in the silicon layer and in the silicon substrate below the oxide layer can be adapted without the need for additional processing steps.

The provision of the silicon wafer with the tunnel oxide layer can be performed in a conventional manner. For example, the provision of a silicon wafer with a tunnel oxide layer can comprise the wet-chemical generation of the tunnel oxide layer or its generation by a plasma process on the silicon wafer. Preferably, the tunnel oxide layer comprises an SiO₂ layer or consists of an SiO₂ layer. By the wet-chemical process or the plasma process, preferably a near-surface region of the silicon wafer is oxidized, which leads to the formation of the tunnel oxide layer of SiO₂. The thickness of the tunnel oxide layer is preferably 0.5 nm to 10 nm and more preferably 1.0 nm to 2.0 nm. When the tunnel oxide layer is wet-chemically generated, the same wet-chemical machine can also be used to wet-chemically clean the surface of the silicon wafer before generating the tunnel oxide layer. When a plasma process is used, this step can be integrated into the sputtering machine.

The first layer of amorphous silicon preferably consists of intrinsic silicon and/or doped silicon, wherein the dopant concentration in the first layer should be smaller than that of the second layer in order to cause diffusion of the dopant by means of the gradient thus achieved. The intrinsic silicon and/or doped silicon can be applied to the tunnel oxide layer in a known manner by means of cathode sputtering. The layer thickness is preferably between 1 nm and 100 nm. The first layer requires a high purity, the concentration of the impurity atoms in the first layer should therefore be considerably smaller than the dopant concentration in the second layer.

The second layer comprising a dopant preferably comprises one or a combination of the following materials: silicon or silicon oxide doped with an element from the 3rd or 5th main group or mixed therewith in a higher concentration, preferably phosphosilicate glass or borosilicate glass, an element from the 3rd or 5th main group as a pure substance or in the form of an oxide. Preferably, the proportion of the element from the 3rd or 5th main group is at least 0.5 mol %, more preferably at least 1 mol %, even more preferably at least 5 mol % and particularly preferably at least 10 mol % of the entire second layer. Perpendicular to the surface, the second layer does not have to be homogeneous but, for example, can also have a concentration gradient of the dopant. Furthermore, the second layer can also consist of two or more sublayers which, for example, comprise more or less dopant (or none at all).

The thickness of the second layer is preferably between 10 nm and 1 μm, more preferably between 50 nm and 200 nm.

In other words, according to the invention, a heavily p- or n-doped silicon-containing layer can be deposited as a dopant source with the aid of cathode sputtering, which in turn is applied to a silicon substrate covered with an oxide layer. The doped layer can consist of one or more undoped and one or more highly doped individual layers. In this connection, all silicon layers can be deposited by means of cathode sputtering. In a subsequent annealing process, sufficient dopant can thus be diffused into an undoped silicon layer as well as into the base material below the oxide layer. Thus, passivated contacts for crystalline silicon solar cells with a high dopant content or a high charge carrier selectivity can be produced.

The additional dopant layer is applied, for example, in the form of a pure substance (for example, boron), a dopant oxide (for example, boron oxide), a doped silicon (for example, Si:B or Si:P) or a doped silicon oxide (for example, doped quartz, boron glass or phosphorus glass). The low-doped or non-doped (intrinsic) silicon-based layer can be located both above and below the highly doped layer. In other words, the first and second layers can also be interchanged according to the invention. Furthermore, a multiple stack of first and second layers can also be produced according to the invention.

As already mentioned, silicon or silicon oxide doped with an element from the 3rd or 5th main group are particularly preferred materials for the second layer. Phosphosilicate glass or borosilicate glass are particularly suitable for this purpose, since these glasses can contain the dopants in concentrations of up to 40%. Such targets can be produced by melting, sintering or spraying.

Depending on whether it is deposited below or above the amorphous or polycrystalline silicon layer, the phosphosilicate or borosilicate glass layer can simultaneously also assume other functions in addition to its function as a dopant source. Between the tunnel oxide layer and the silicon layer, a highly doped glass layer can reinforce the tunnel oxide and thus make it temperature-stable. When the phosphosilicate or borosilicate glass layer is deposited above the silicon layer, the intended dopant profile can be tailored by the thickness, the density and the dopant concentration of the glass layer. In this location, the doped oxide layer can also assume the additional function of a passivation layer and/or a layer for controlling the diffusion properties of a metal paste applied later, e.g. by screen printing, for contacting the doped second or third layer.

By the combination of oxide, silicon and doped layers, it can be achieved, by adjusting dopant concentrations and diffusion properties (thickness and density of the layers), that in only one subsequent thermal process step not only a highly doped polycrystalline layer is produced, but independently also a desired dopant profile is selectively adjusted above and/or below the tunnel oxide. Thus, a passivated contact with an adjustable dopant profile can be generated with only three process steps. Ideally, this thermal process step can also be used simultaneously for contacting the doped Si layers (second or third layer) by means of a metal paste.

Preferably, the first layer and the second layer are applied in the same cathode sputtering machine, whereby the manufacturing process becomes particularly simple and cost-efficient. Ideally, the tunnel oxide is also deposited in the same machine by means of a plasma process.

In addition to producing a highly doped silicon layer by means of diffusion of the dopant and electronic activation of the dopant into the silicon crystal lattice, the annealing step preferably also causes that the first layer of amorphous silicon is converted into a doped polycrystalline silicon layer, and optionally that a silicon layer doped with the dopant of the second layer is formed directly below the tunnel oxide layer in the silicon wafer, wherein the dopant concentration drops across said silicon layer preferably by at least two orders of magnitude compared to the polycrystalline silicon layer, .i.e. the dopant concentration at the lower end of the doped silicon layer (into the silicon wafer) is preferably at most 1% of the dopant concentration of the polycrystalline silicon layer. Preferably, this dopant gradient is formed below the tunnel oxide in a region extending from the tunnel oxide layer to a maximum of 50 nm below the tunnel oxide layer, preferably to a maximum of 30 nm below the tunnel oxide layer. The size of this region as well as the drop of the dopant concentration is adjusted via the temperature and time of the annealing step. Too heavy doping by thermal diffusion increases the number of defects, too light doping increases the recombination at the interface of the tunnel oxide. Subsequently, the electrically active dopant concentration in the doped polycrystalline silicon layer and/or in the tunnel oxide-near region of the doped silicon layer is at least 1×10²⁰ cm⁻³ in the case of p-doping and at least 5×10¹⁹ cm⁻³ in the case of n-doping.

The method according to the invention can comprise further process steps for producing a starting material for a silicon solar cell with passivated contacts and/or for producing such a silicon solar cell. For example, a classical diffused emitter can be produced on the opposite side.

Accordingly, the method according to the invention preferably comprises the following steps: coating the side of the silicon wafer opposite the tunnel oxide layer with at least one third layer comprising a dopant by means of cathode sputtering. Preferably, the third layer comprises one or a combination of the following materials: silicon or silicon oxide doped with an element from the 3rd or 5th main group, preferably phosphosilicate glass or borosilicate glass, an element from the 3rd or 5th main group as a pure substance or in the form of an oxide. Preferably, the second and third layers are oppositely doped, so that, for example, the material of the second layer is doped with an element from the 3rd main group and the material of the third layer is doped with an element from the 5th main group, or vice versa, so that the one doped layer forms a p-n junction (emitter) in conjunction with the likewise doped silicon wafer and the other, oppositely doped layer forms a surface field for field passivation of the wafer side opposite the emitter. Depending on the cell structure, it is possible with the doped layers to form an emitter or field passivation either directly on a wafer surface (e.g. as a diffused emitter) or on a tunnel oxide layer as a passivated contact.

The formation of a doped emitter is also achieved by the annealing step. In other words, the annealing step preferably causes that a silicon layer doped with the dopant of the third layer is formed below the third layer in the silicon wafer. In each case, the term “below” does not mean a spatial arrangement from top to bottom (which would depend on the orientation of the stack of layers). Rather, it refers to the region of the silicon wafer directly adjacent to the third layer.

Alternatively, the starting material or the silicon solar cell can also be provided with passivated contacts on both sides. Accordingly, it is preferred that the silicon wafer is provided with a tunnel oxide layer on both sides and that the method further comprises: coating each of the two tunnel oxide layers with at least one first layer of amorphous silicon by means of cathode sputtering, and coating each of the two first layers with at least one second layer comprising a dopant by means of cathode sputtering. In the present case, the aforementioned preferred features for the tunnel oxide layer, the first layer and the second layer, of course, respectively apply to the layers of both sides. For example, the annealing process preferably causes a simultaneous conversion of each of the first layers of amorphous silicon on both sides into a doped polycrystalline silicon layer, and/or a simultaneous formation of a doped silicon layer in the silicon wafer below each of the tunnel oxide layers.

Preferably, the second layer and/or the third layer can be coated with a hydrogen-enriched cover layer comprising a nitride and/or an oxide, preferably a hydrogen-enriched silicon nitride. Typical layers contain 4-40 at % of hydrogen. Due to the total thermal budget of all processes, this percentage is reduced by diffusion during the thermal treatment and the diffusing hydrogen is made available for the chemical passivation of crystal defects.

As has already become clear, the method according to the invention can be applied to the doping of the opposing surfaces of solar cells with opposite polarity with the aid of layer systems consisting of different combinations of diffusion barriers, oxides, dopant layers and silicon layers. Thus, cells with either passivated contacts of different polarity with selectively adjustable dopant profiles on both sides or with a passivated contact on one side and an opposite diffused emitter can also be generated by means of suitable layer systems on the opposite surfaces of the silicon substrate. By adjusting the dopant concentrations and the diffusion properties of the stacks of layers, it is possible to form the desired structures on both the front side and the back side of the solar cell in a single annealing step.

Compared to the processes commonly used today, the cell manufacturing process can be considerably simplified by the application of two or three of the aforementioned process steps on both sides as well as the subsequent application of passivation layers, since, on the one hand, several layer deposition processes can be combined in one machine, and, on the other hand, coating is possible purely on one side due to the sputtering process and therefore additional masking or cleaning steps can be dispensed with and the annealing process required to form polycrystalline silicon layers can be carried out in a simplified manner without toxic dopants.

Although the co-sputtering of silicon and dopant described in WO 2018/102852 A1 also enables the production of a correspondingly doped layer in a single manufacturing step, it is disadvantageous for the reasons described at the beginning. Furthermore, the method according to the invention allows a much better control and adjustment of the dopant concentration and in particular of a dopant gradient than is possible by means of co-sputtering. With respect to the latter, WO 2018/102852 A1 also mentions the possibility of a pulsed deposition, in which the deposition of the dopant is interrupted. However, this is only possible in the case of a static deposition, which is not feasible in the context of an industrial mass production. In contrast, the method of the present invention allows coating in a continuous process, in which the silicon wafers to be coated are moved at a, preferably constant, speed relative to the sputtering cathodes (or vice versa). Preferably, this relative motion is a linear motion of the wafers. However, other forms of motion, such as, for example, a rotation or motions along curved paths, are also possible. In such a continuous process, coating with the first and second layers is carried out by means of separate sputtering cathodes which are spaced apart from each other and by means of which firstly (at a first position of the wafer in the machine) the amorphous silicon is applied and subsequently (at a second position of the wafer in the machine) the dopant is applied. In other words, the two layers are applied in separate process steps, locally separated from each other, which allows, on the one hand, a continuous production in a continuous process and, on the other hand, a better control of each individual process step. Accordingly, it is preferred that the silicon wafer is moved, preferably at a constant speed, during the two coatings with the first and second layers as well as between the two coatings. This speed can be, for example, between 1 and 3 m/min.

For the production in a continuous process, a continuous train is preferably formed from a plurality of substrate carriers (so-called “carriers”), preferably in a part of the process space. This train of essentially directly adjacent substrate carriers, on which the wafers are supported, is passed under the sputtering cathodes at a constant speed, whereby the coating can be used efficiently, since no coating material is lost, for example, between successive wafers. After coating with the layers according to the invention, the train is preferably disintegrated again, i.e., separated into individual substrate carriers (or substrate carrier groups), since this simplifies their removal.

The present invention is further directed to a method for producing a silicon solar cell based on the above-described method for producing a starting material for a silicon solar cell. This method for producing a silicon solar cell with passivated contacts further comprises the step of applying a metal contact to a back surface and applying metal contacts on a front surface of the starting material. As is known to the skilled person, further steps may be required for this purpose, such as, for example, cleaning and/or etching the surface after coating the second or third layer, in order to create the conditions for applying the metal contacts. The application of the metal contacts is typically carried out by screen printing and usually also requires an annealing or firing step. Alternatively, transparent conductive oxides or metals applied by PVD can also serve as contact layers.

The present invention is further directed to a machine for producing a starting material for a silicon solar cell with passivated contacts. The machine comprises a first cathode sputtering unit adapted to coat a substrate with at least one first layer of amorphous silicon. Further, the machine comprises a second cathode sputtering unit adapted to coat the first layer with at least one second layer comprising a dopant. In this regard, the first and second cathode sputtering devices are integrated in a common vacuum process section of the machine.

Optionally, an annealing unit is further provided which is adapted to anneal the substrate coated with the first and second layers at a temperature of at least 700° C. This annealing unit can be an integral component of the machine according to the invention or, alternatively, can be provided as a separate unit which can be connected to the rest of the machine via a process section or can be completely separate therefrom.

The first and second cathode sputtering units can be conventional cathode sputtering units. The cathode sputtering units comprise, for example, planar or tubular magnetrons as linear coating sources, into which the sputtering targets made of suitable materials are incorporated and removed during the cathode sputtering process in the plasma. The suitability for coating with the specific first or second layer primarily results from the respective target of the cathode sputtering unit. Also, the cathode sputtering unit is preferably configured such that the sputtering damage, i.e. the amount of defects in or under the deposited material, is low. This can be achieved by measures such as the use of an active anode or a relatively strong and balanced magnet configuration. Accordingly, the target of the second cathode sputtering unit preferably comprises one or a combination of the following materials: silicon or silicon oxide doped with an element from the 3rd or 5th main group, preferably phosphosilicate glass or borosilicate glass, an element from the 3rd or 5th main group as a pure substance or in the form of an oxide. The proportion of the element from the 3rd or 5th main group is preferably at least 0.5 mol %, more preferably at least 1 mol %, even more preferably at least 5 mol % and particularly preferably at least 10 mol %.

The target of the first cathode sputtering unit preferably consists of silicon, wherein the degree of purity of the first target should be significantly better than the degree of doping of the target of the second or third layer.

Preferably, the first and second cathode sputtering devices are spaced apart from each other along the process section so that there is no line of sight between the two cathodes. This can be achieved with the aid of spatial distance and screens. Typically, planar sputtering cathodes have a width between 8 and 20 cm in the moving direction of the substrate and tubular sputtering cathodes have an outer diameter of 8 to 20 cm. Between the spatial ends of the cathodes in the moving direction of the substrate, there must still be at least the dark space distance (i.e., a discharge-free space) of a few millimeters. Therefore, a spatial distance of at least 10 cm of the outer sides of the cathodes from each other is preferred, and a spatial distance of at least 30 cm is particularly preferred.

According to the invention, a third cathode sputtering unit can also be provided, which is adapted to coat the substrate on the side opposite the first layer with at least one third layer comprising a dopant. Preferably, the first, second and third cathode sputtering devices are integrated in a common vacuum process section of the machine. Preferably, the machine comprises a mechanism for conveying the substrates, wherein preferably the first and second cathode sputtering units are arranged on one side of the substrate conveying unit and the third cathode sputtering unit is disposed on the opposite side of the conveying unit.

The target of the third cathode sputtering unit preferably comprises one or a combination of the following materials: silicon or silicon oxide doped with an element from the 3rd or 5th main group, preferably phosphosilicate glass or borosilicate glass, an element from the 3rd or 5th main group as a pure substance or in the form of an oxide. In this context, the materials of the second and third targets are preferably oppositely doped.

As an alternative to this third cathode sputtering unit, the machine according to the invention can also comprise a third cathode sputtering unit adapted to coat the substrate on the side opposite the first layer with at least one first layer of amorphous silicon. Furthermore, a fourth cathode sputtering unit can be provided, which is adapted to coat the first layer with at least one second layer comprising a dopant. Preferably, the first, second, third and fourth cathode sputtering devices are integrated in a common vacuum process section of the machine. The targets of the third and fourth cathode sputtering units preferably comprise the aforementioned materials of the targets of the first and second cathode sputtering units. Furthermore, it is also true for this embodiment that preferably the first and second cathode sputtering units are arranged on a first side of the substrate conveying device and the third and fourth cathode sputtering units are arranged on the opposite side of the substrate conveying device.

Preferably, the machine comprises a further, upstream cathode sputtering unit by means of which the tunnel oxide layer is applied from a silicon-containing sputtering target with the aid of an oxygen-containing process gas (e.g., O₂, CO₂). Due to the oxygen-containing gases, this further cathode sputtering unit is then preferably separated from the first and second cathode sputtering units via gas separation. Alternatively, the machine can comprise a plasma unit adapted to clean a silicon wafer by a plasma process and/or provide it with a tunnel oxide layer. Alternatively, the machine can further comprise an upstream wet-chemical unit adapted to provide a silicon wafer with a tunnel oxide layer by a wet-chemical process.

The present invention allows the combined generation of polycrystalline passivated contacts and the selective adjustment of doping profiles and thus a greatly shortened process flow for producing cells with passivated contacts. So far, it has been necessary to deposit the doped silicon layer, for example, by means of LPCVD (low pressure chemical vapor deposition), in order to produce highly doped passivated contacts. Since LPCVD does not allow substrates to be coated exclusively on one side, the opposite side of the solar cell is thus generally also doped with the wrong polarity. This is undesirable and must either be prevented from the outset by applying a protective mask, or the doping on the front side must be subsequently removed again. The problem of too low doping and the problem of the doping profile not being independently adjustable during the thermal step can be solved by selectively applying the first and second layers on one side using the sputtering process, which can be used on one side, and by selectively adjusting the concentration of the dopant source and the diffusion properties of diffusion barriers. Due to suitable layer systems, the method according to the invention can even be applied for both sides of the solar cells with different polarities and diffusion rates.

Additional advantages of sputtering are the easy handling and controllability of the method as well as the renunciation of toxic gases.

In particular, the method according to the invention makes it possible to apply both the silicon layer and an additional doping source in two successive processes in a single machine. Thus, it is possible to achieve doping on one side of the applied silicon layer in a subsequent thermal step. By means of the sputtering process, both the silicon layer and, for example, a phosphosilicate or borosilicate glass layer can be applied on one side. By selecting the layer thickness and the concentration of the dopant in the target material, the dopant concentration can be precisely adjusted.

Typical diffusion temperatures range from 700° C. to 1100° C. The choice of the interfacial oxide determines, for example, the temperature stability, wherein a smaller oxide thickness leads to a lower stability during annealing. By means of the combination with further oxide layers, even a thermally unstable, wet-chemical tunnel oxide can be stabilized. The adjustment of the doping profiles can be carried out on the opposite sides of the solar cell with the aid of suitable layer systems of different polarity in a common annealing step.

The increase of the doping layer thickness or a further, so-called capping layer deposited by sputtering can support the directed diffusion of the dopant into the silicon layer and/or reduce the diffusion out of it into the environment. Moreover, a (further) source of hydrogen can thereby be applied for the passivation of the interfaces.

The phosphosilicate or borosilicate glass dopant layer, when applied as the last layer, can also be used as a passivation layer, if necessary.

All sputtering processes, on both the front side and the back side of the solar cell, can take place in a single sputtering machine.

The diffusion properties on both sides of the cell can be adjusted by means of different layer systems such that a thermal profile achieves the desired dopant profiles on both sides.

As already stated above, the dopant layer can be provided above or below the silicon layer. In other words, according to the invention, the positions of the first and second layers can be interchanged. As also already stated above, the silicon wafer can be provided with a p-doped layer on one side and an n-doped layer on the opposite side. Furthermore, the cell can be provided with passivated contacts on both sides or with a passivated contact on one side and a classical diffused emitter on the other side.

In the following, preferred embodiments of the present invention will be described in more detail with reference to the Figures, in which:

FIG. 1 shows a cross-section through a solar cell with charge carrier-selective, polycrystalline silicon contacts according to a preferred embodiment of the present invention;

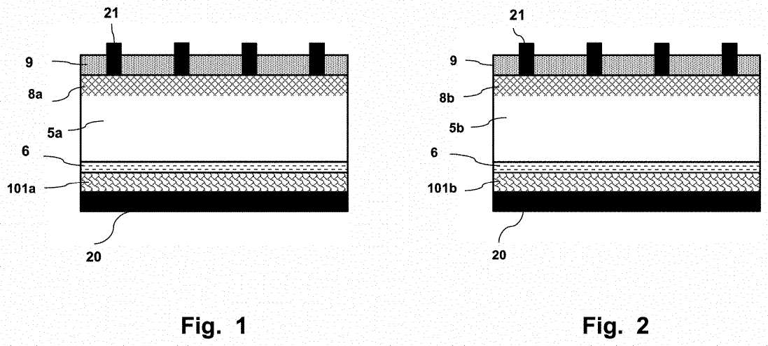

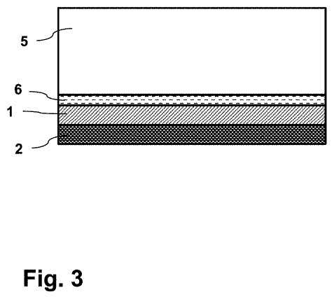

FIG. 2 shows a cross-section through a solar cell with charge carrier-selective, polycrystalline silicon contacts according to a further preferred embodiment of the present invention;

FIG. 3 shows a cross-section through a starting material for a silicon solar cell with passivated contacts before the annealing step according to a preferred embodiment of the present invention;

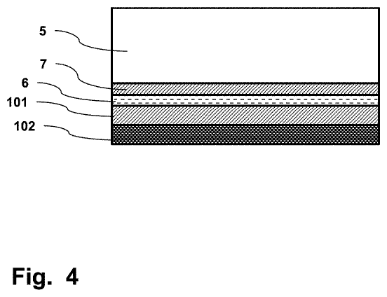

FIG. 4 shows the starting material according to FIG. 3 after the annealing step;

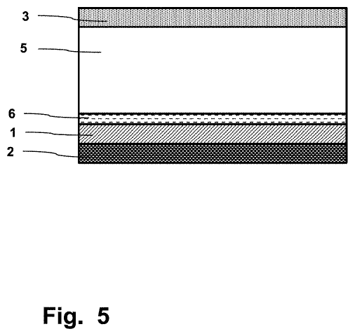

FIG. 5 shows a starting material for a silicon solar cell with passivated contacts before the annealing step according to a preferred embodiment of the present invention;

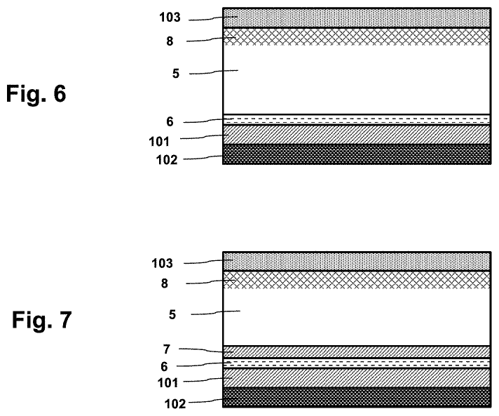

FIG. 6 shows the starting material according to FIG. 5 after the annealing step according to a first variant;

FIG. 7 shows the starting material according to FIG. 5 after the annealing step according to a second variant;

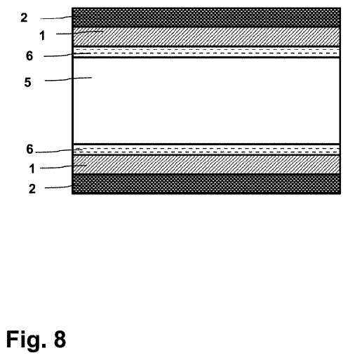

FIG. 8 shows the starting material for a silicon solar cell with passivated contacts before the annealing step according to a further preferred embodiment of the present invention;

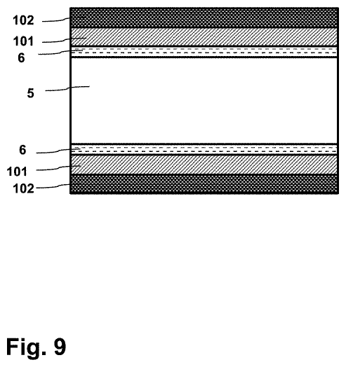

FIG. 9 shows the starting material according to FIG. 8 after the annealing step according to a first variant;

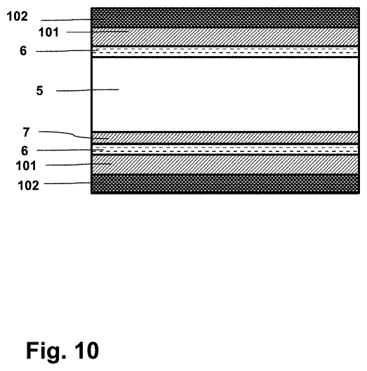

FIG. 10 shows the starting material according to FIG. 8 after the annealing step according to a second variant;

FIG. 11 shows the starting material according to FIG. 8 after the annealing step according to a third variant;

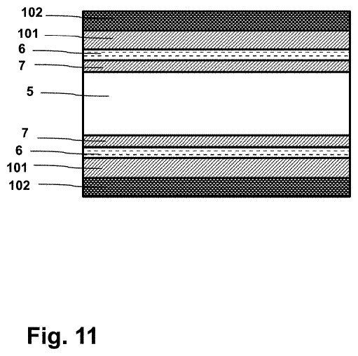

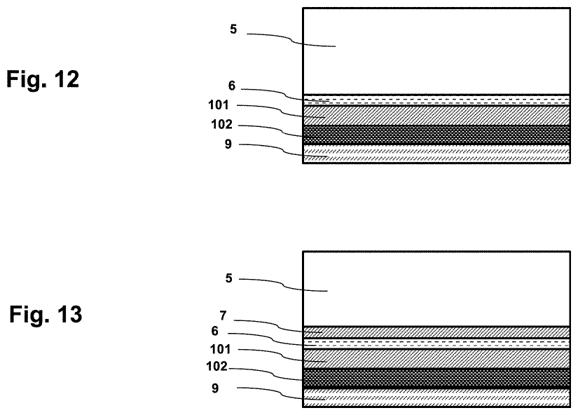

FIG. 12 shows a starting material for a silicon solar cell with passivated contacts according to a further preferred embodiment of the present invention;

FIG. 13 shows a starting material for a silicon solar cell with passivated contacts according to a further preferred embodiment of the present invention;

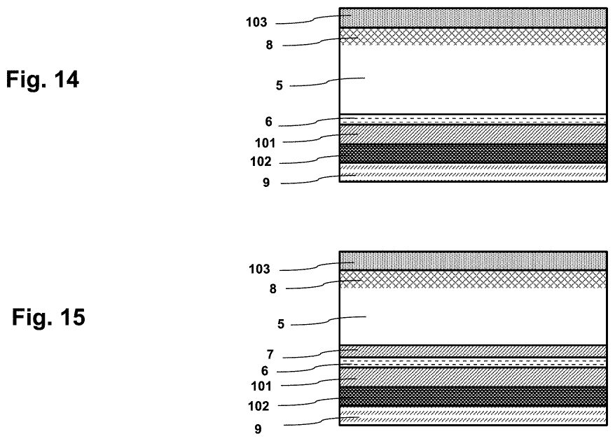

FIG. 14 shows a starting material for a silicon solar cell with passivated contacts according to a further preferred embodiment of the present invention;

FIG. 15 shows a starting material for a silicon solar cell with passivated contacts according to a further preferred embodiment of the present invention;

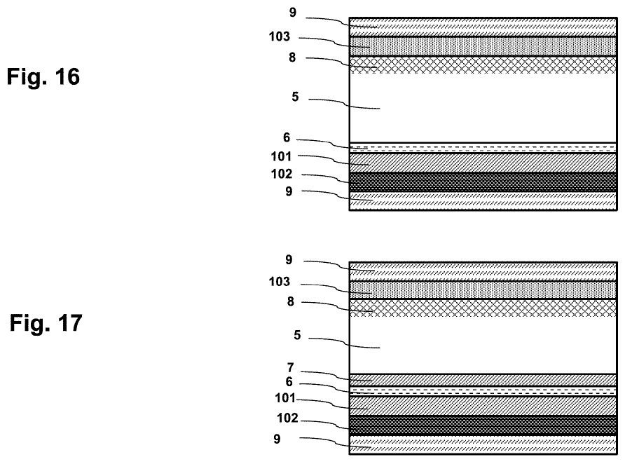

FIG. 16 shows a starting material for a silicon solar cell with passivated contacts according to a further preferred embodiment of the present invention;

FIG. 17 shows a starting material for a silicon solar cell with passivated contacts according to a further preferred embodiment of the present invention;

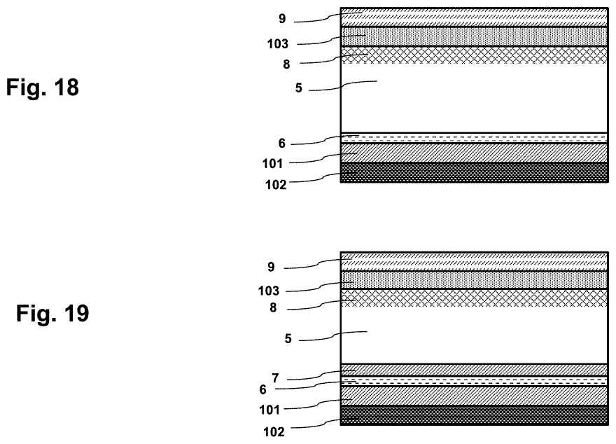

FIG. 18 shows a starting material for a silicon solar cell with passivated contacts according to a further preferred embodiment of the present invention;

FIG. 19 shows a starting material for a silicon solar cell with passivated contacts according to a further preferred embodiment of the present invention;

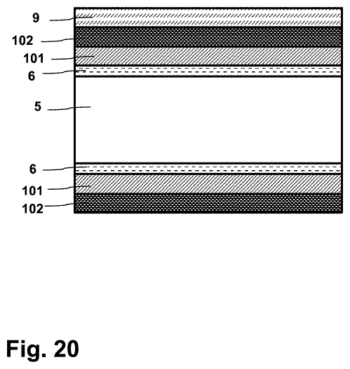

FIG. 20 shows a starting material for a silicon solar cell with passivated contacts according to a further preferred embodiment of the present invention;

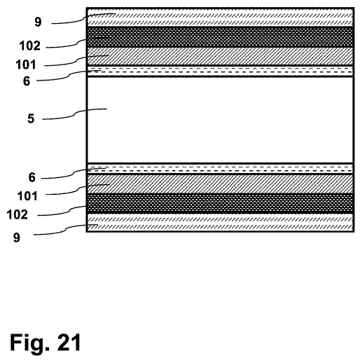

FIG. 21 shows a starting material for a silicon solar cell with passivated contacts according to a further preferred embodiment of the present invention;

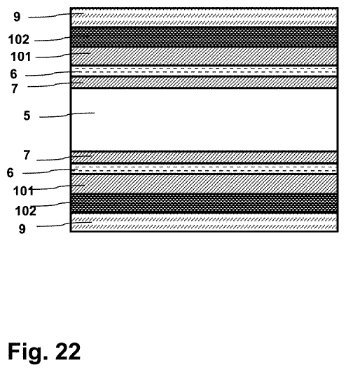

FIG. 22 shows a starting material for a silicon solar cell with passivated contacts according to a further preferred embodiment of the present invention;

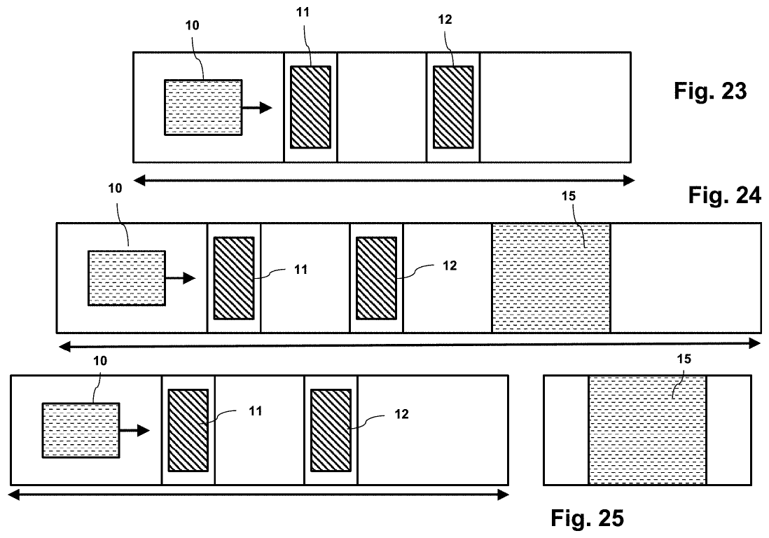

FIG. 23 shows a schematic diagram of a machine for producing a starting material for a silicon solar cell with passivated contacts according to a preferred embodiment of the present invention;

FIG. 24 shows a schematic diagram of a machine for producing a starting material for a silicon solar cell with passivated contacts according to a preferred embodiment of the present invention;

FIG. 25 shows a schematic diagram of a machine for producing a starting material for a silicon solar cell with passivated contacts according to a preferred embodiment of the present invention;

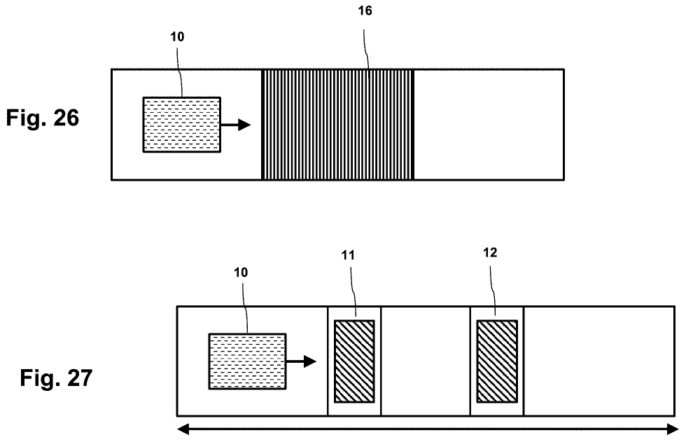

FIG. 26 shows a schematic diagram of a machine for producing a starting material for a silicon solar cell with passivated contacts according to a preferred embodiment of the present invention;

FIG. 27 shows a schematic diagram of a machine for producing a starting material for a silicon solar cell with passivated contacts according to a preferred embodiment of the present invention;

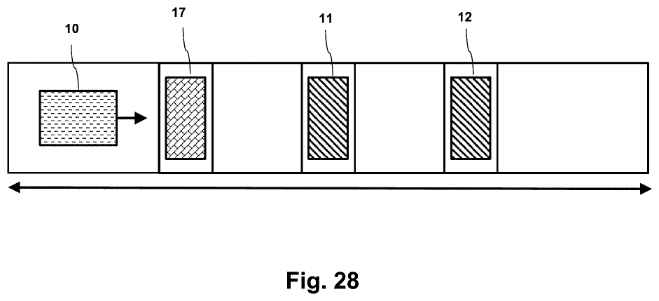

FIG. 28 shows a schematic diagram of a machine for producing a starting material for a silicon solar cell with passivated contacts according to a preferred embodiment of the present invention;

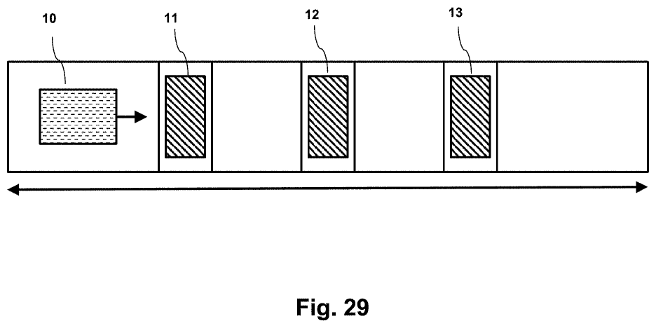

FIG. 29 shows a schematic diagram of a machine for producing a starting material for a silicon solar cell with passivated contacts according to a preferred embodiment of the present invention; and

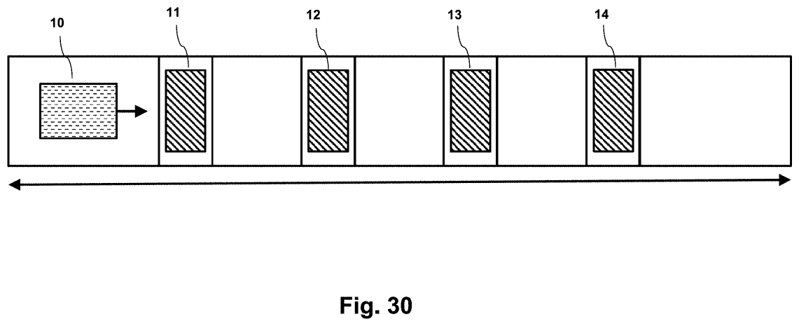

FIG. 30 shows a schematic diagram of a machine for producing a starting material for a silicon solar cell with passivated contacts according to a preferred embodiment of the present invention.

FIGS. 1 and 2, illustrate cross-sections through silicon solar cells with passivated contacts analogous to those shown in FIG. 1 of WO 2018/102852 A1. In FIG. 1, a p-doped silicon wafer 5a is provided with an n⁺ diffusion layer 8a and an SiN_{X} layer 9. The latter is penetrated by the metal contacts 21 of the front side. On the back side of the wafer 5a there is an SiO_{X} tunnel oxide layer 6 as well as a p⁺-doped polycrystalline silicon layer 101a, on which the metal contact 20 of the back side is arranged.

FIG. 2 shows an analogous cell with an n-doped silicon wafer 5b, a p⁺ diffusion layer 8b, and an n⁺-doped polycrystalline silicon layer 101b.

As has already been explained in detail, it is an object of the present invention to provide an improved method for producing a starting material for such a silicon solar cell with passivated contacts, with the aid of which a respectively high dopant concentration can be achieved in a simple manner.

According to the invention, a silicon wafer 5 (cf. FIG. 3) with a tunnel oxide layer 6 is provided for this purpose and the tunnel oxide layer 6 is coated with at least one first layer 1 of amorphous silicon by means of cathode sputtering. The first layer 1 is then coated with at least one second layer 2 comprising a dopant by means of cathode sputtering. The result of these two coating processes can be seen in a schematic cross-sectional view in FIG. 3. The tunnel oxide layer 6 preferably consists of SiO₂ and preferably has a thickness between 0.5 nm and 10 nm. The first layer 1 of amorphous silicon preferably consists of intrinsic silicon and/or doped silicon and preferably has a thickness between 1 and 100 nm. The second layer 2 preferably comprises one or a combination of the following materials: silicon or silicon oxide doped with an element from the 3rd or 5th main group, preferably phosphosilicate glass or borosilicate glass, an element from the 3rd or 5th main group as a pure substance or in the form of an oxide.

According to the invention, the coated silicon wafer 5 (including layers 1, 2 and 6 as well as, where applicable, further layers) is annealed at a temperature of at least 700° C. This annealing step preferably causes diffusion of the dopant contained in the second layer 2 into the adjacent first layer 1 of amorphous silicon and optionally through the tunnel oxide layer 6 into the region of the silicon wafer 5 directly adjacent to the tunnel oxide layer 6. In other words, the annealing step preferably causes that the first layer 1 of amorphous silicon is converted into a doped polycrystalline silicon layer 101 (cf. FIG. 4) and that optionally a silicon layer 7 doped with the dopant of the second layer 2 is formed below the tunnel oxide layer 6 in the silicon wafer 5.

An example of the result of such an annealing step, in which likewise a silicon layer 7 doped with the dopant of the second layer 2 is formed below the tunnel oxide layer 6 in the silicon wafer 5, is schematically shown in FIG. 4.

Preferably, the dopant concentration in the doped polycrystalline silicon layer 101 is at least 1×10²⁰ cm⁻³ in the case of p-doping and at least 5×10¹⁹ cm⁻³ in the case of n-doping. The second layer 2 (cf. FIG. 3) is denoted by reference sign 102 after the annealing step (cf. FIG. 4), since its dopant concentration may be reduced, compared to its state before the annealing step, due to the diffusion of the dopant into the layers 101 and 7. The thicknesses of layers 6, 101 and 102 after the annealing step are essentially the same as the thicknesses of layers 6, 1 and 2 before the annealing step. The silicon layer 7 doped with the dopant of the second layer 2 preferably has a thickness between 50 and 200 nm.

Furthermore, according to the invention, the side of the silicon wafer 5 opposite the tunnel oxide layer 6 can be coated with at least one third layer 3 comprising a dopant. This coating with the third layer 3 is preferably also carried out before the annealing step described above. The result of the coating is schematically shown in FIG. 5.

Analogous to the materials of the second layer 2, the third layer 3 can comprise one or a combination of the following materials: silicon or silicon oxide doped with an element from the 3rd or 5th main group, preferably phosphosilicate glass or borosilicate glass, an element from the 3rd or 5th main group as a pure substance or in the form of an oxide, wherein the second layer 2 and the third layer 3 preferably are oppositely doped. This leads to corresponding n- and p-doped layers analogously to FIGS. 1 and 2.

Depending on the thicknesses, dopant concentrations and diffusion properties of the individual layers as well as the parameters selected during annealing, annealing the layer sequence according to FIG. 5 can lead to a starting material according to FIG. 6 or to an alternative starting material according to FIG. 7. In both cases, the annealing process causes that a silicon layer 8 doped with the dopant of the third layer 3 is formed below the third layer 3, 103 in the silicon wafer 5. In both cases, the annealing process further causes that the first layer 1 of amorphous silicon is transformed into a doped polycrystalline silicon layer 101. Depending on whether the dopant from the second layer 2 diffuses through the tunnel oxide layer 6 into the silicon wafer 5 adjacent thereto, the annealing step can additionally cause that a silicon layer 7 doped with the dopant from the second layer 2 is formed below the tunnel oxide layer 6 in the silicon wafer 5. The latter alternative is shown in FIG. 7.

The layer sequence according to FIGS. 5 to 7 can be used, for example, as a starting material for a silicon solar cell with passivated contacts on one side and a classical diffused emitter on the other side. Alternatively, the method according to the invention can also be used for producing a starting material for a silicon solar cell with passivated contacts on both sides.

For this purpose, a silicon wafer 5 is preferably provided on both sides with corresponding tunnel oxide layers 6 (cf. FIG. 8). Subsequently, each of the two tunnel oxide layers 6 is coated with at least one first layer 1 of amorphous silicon and each of the two first layers 1 is coated with at least one second layer 2 comprising a dopant. The result of these coating processes is schematically illustrated in FIG. 8.

This stack of layers is then annealed at a temperature of at least 700° C., which, analogously to the above statements, causes that each of the first layers 1 of amorphous silicon is converted into a doped polycrystalline silicon layer 101 on both sides. This conversion takes place essentially simultaneously in the course of a common annealing step.

The result of such an annealing step is again schematically shown in FIG. 9. Analogously to the above statements, however, starting materials with layer sequences corresponding to FIGS. 10 and 11 can also be achieved by the annealing step when the annealing process causes a formation of a doped silicon layer 7 below one of (cf. FIG. 10) or below each of the two tunnel oxide layers 6 (cf. FIG. 11) in the silicon wafer 5.

It is further preferred that the second layer 2 and/or the third layer 3 is coated with a hydrogen-enriched cover layer 9 comprising a nitride and/or an oxide, preferably a hydrogen-enriched silicon nitride. In FIGS. 12 to 22, the preferred embodiments of the starting material according to the invention as already discussed above are schematically illustrated in each case with one or two such cover layers 9. FIGS. 12 to 22 show the starting material in each case after the annealing step, so that the cover layer 9 is in each case on the second layer 102 and/or the third layer 103 after the annealing step.

FIGS. 23 to 30 schematically illustrate preferred embodiments of the machine according to the invention for producing a starting material for a silicon solar cell with passivated contacts. As shown in FIG. 23, such a machine comprises a first cathode sputtering unit 11 adapted to coat at least one substrate 10 with at least one first layer of amorphous silicon. The machine further comprises a second sputtering unit 12 adapted to coat the first layer with at least one second layer comprising a dopant. The first cathode sputtering device 11 and the second cathode sputtering device 12 are integrated in a common vacuum process section of the machine, which is symbolized by the double arrow.

Optionally, an annealing unit 15 can be provided (cf. FIG. 24), which is adapted to anneal the substrate coated with the first and second layers at a temperature of at least 700° C. The annealing unit 15 can be integrated in the same vacuum process section, as schematically illustrated in FIG. 24, or represent a separate module (cf. FIG. 25).

The machine can further comprise an upstream wet-chemical unit 16 (cf. FIG. 26), which is adapted to provide a silicon wafer with a tunnel oxide layer by means of a wet-chemical process. This wet-chemical unit 16 can be a separate module, which is connected to the vacuum process section according to FIG. 27 via a process section or forms a completely separate unit.

Alternatively, a plasma unit 17 can be provided (cf. FIG. 28), which is adapted to provide a silicon wafer with a tunnel oxide layer by means of a plasma process. Together with the first cathode sputtering device 11 and the second cathode sputtering device 12, the plasma unit 17 can be integrated in a common vacuum process section of the machine, which is also symbolized by the double arrow in FIG. 28. Alternatively, the plasma unit 17 can also form a separate module.

The machine can further comprise a third cathode sputtering unit 13 adapted to coat the substrate on the side opposite the first layer with at least one third layer comprising a dopant. The first cathode sputtering device 11, the second cathode sputtering device 12 and the third cathode sputtering device 13 are preferably integrated in a common vacuum process section of the machine, as schematically illustrated in FIG. 29.

Alternatively, the machine can include a third cathode sputtering unit 13 adapted to coat the substrate on the side opposite the first layer with at least one first layer of amorphous silicon, as well as a fourth cathode sputtering unit 14 adapted to coat the first layer with at least one second layer comprising a dopant. As can be seen in FIG. 30, the first cathode sputtering device 11, the second cathode sputtering device 12, the third cathode sputtering device 13 and the fourth cathode sputtering device 14 are preferably integrated in a common vacuum process section of the machine, which is again symbolically represented by the double arrow.

In the following, a concrete embodiment of the method according to the invention will be described in detail.

The starting point was a silicon wafer with the following properties: p-type monocrystalline wafer material with a typical conductivity of 10 Ohm*cm. After wet-chemically cleaning the wafers, using, for example, RCA or an alternative industrial cleaning process with acidic or alkaline media (for example KOH/H₂O₂), at least the front side of the wafers was subjected to wet-chemical alkaline texturing (e.g. using KOH and an additive, for example CellTex). Subsequently, a tunnel oxide of a thickness of approximately 1.4 nm was generated only on the back side of the wafer in a bath with an ozone-containing solution at an elevated temperature.

The tunnel oxide layer of the silicon wafer was then coated with a first layer of amorphous silicon. For this purpose, a horizontal sputtering machine of the type GENERIS from the company SINGULUS TECHNOLOGIES AG was used, in which up to 64 wafers per substrate carrier are transported at a constant linear speed of approximately 1 to 3 m/min through the evacuated process area comprising one or more linear coating sources, for example with planar or cylindrical magnetrons. Typical process conditions were: sputtering pressure/gas: 8×10⁻³ mbar/argon, wafer temperature: 200° C., sputtering targets: planar Si sputtering targets with 5N purity, electrical excitation: DC with a power density of 3 W/cm².

The first layer of amorphous silicon thus formed has a thickness of 20 nm. Subsequently, a second layer with a layer thickness of 100 nm was applied to the first layer in the same sputtering machine. The sputtering target was a planar phosphosilicate glass with a phosphorus doping of >1%.

In the subsequent annealing step, the electrical activation and diffusion of the doping and at the same time the conversion of the amorphous silicon layer into a polycrystalline silicon layer took place in a furnace under N₂ inert gas at 800° C.-850° C. for <30 min.

Subsequently, the front side was optionally post-cleaned (HF dip), then coated with approximately 10 nm AlOx and then both sides, the front side and the annealed layer on the back side, were each covered with an SiN:H layer of a thickness of 80 nm. These coatings were performed according to typical PERC solar cell recipes at a substrate temperature of approximately 400° C. in a PECVD machine, likewise of the type GENERIS from the company SINGULUS TECHNOLOGIES AG. For classical PERC solar cells, the AlOx+SiN:H layer system is applied to the back side, here on the textured front side. For this purpose, adjustments had to be made in the layer thickness as well as in the gas ratio SiH4:NH3 for SiN:H and TMAL+Ar+N₂O for AlOx. The plasma sources used for this CVD process were inductively driven at 13.56 MHz and linearly arranged.

As already mentioned, the present invention enables the production within the scope of a continuous process, for example by means of the aforementioned sputtering machine of the type GENERIS from the company SINGULUS TECHNOLOGIES AG.

For this purpose, the wafers are located on a substrate carrier in pockets, typically 30 to 80 wafers per carrier, depending on the size of the wafers (typical square wafer sizes: M0-G12 (156 mm-210 mm), typical round wafer sizes: 1″-300 mm). These substrate carriers are usually loaded in air (dust-free enclosure) with low-contact/contactless grippers.

Subsequently, individual carriers (or carrier groups) are introduced in a so-called loadlock chamber. After the introduction of the carrier(s), this chamber is pumped down from 1,000 mbar to about 1 mbar. The typical cycle time therefor (including flap movements, pumping down, transport of the carrier(s), flooding, transport of next carrier(s)) is 25 s-120 s. Optionally, multi-stage loadlocks can also be used for the introduction, i.e., an extension by a further chamber which also runs in cycle mode, but in which the vacuum is brought from approximately 1 mbar to, for example, 10⁻⁴ mbar.

Optionally, the wafers are then subjected to a cleaning process by excited gas in the plasma (DC glow or RF bias indirectly at the chamber or atom/ion sources directed at the wafers).

For the further production in a continuous process, a continuous train is then formed from a plurality of substrate carriers, as already explained above. This train formation takes place in the so-called extension chamber (which is part of the process space). This train of essentially directly adjacent substrate carriers, on which the wafers are supported, is passed under the sputtering cathodes at a constant speed, whereby the coating can be used efficiently, since no coating material is lost, for example, between successive wafers.

The cathodes used in the sputtering process can comprise planar or tubular targets as the sputtering targets. The following parameters are preferably used in the sputtering process:
coating width: >600 mm, better>1,000 mm
power: planar target: >3 W/cm², preferably >5 W/cm²
   tubular target: >6 kW/m, preferably >10 kW/m
basic pressure for process: <5×10⁻⁵ mbar, better<10⁻⁶ mbar
optionally: cold trap to freeze out the water
working pressure for process: 10⁻⁴-10⁻² mbar
heated process area: heaters enable substrate temperature of at least 200° C.,
   better>400° C.

If the tunnel oxide layer is also applied by means of sputtering (top side and/or bottom side of the wafer), the coating sequence according to the invention is:
sputtering source(s) for deposition of the tunnel oxide (e.g. SiO₂)
gas separation due to O-containing gases
sputtering source(s) for deposition of the intrinsic material (e.g. a-Si:H)
sputtering source(s) for deposition of the highly doped material (e.g. a-Si:P)

Preferably, firstly the tunnel oxide is applied at the top and bottom, then a gas separation takes place, subsequently the other layers are applied at the top and bottom. For all coatings, the carriers are passed through the continuous processing machine in a continuous train.

After coating with the layers according to the invention, the train is disintegrated again i.e., separated into individual substrate carriers (or substrate carrier groups), since this simplifies their removal.

The removal then takes place analogously or inversely to the introduction, unloading takes place either before or after the return transport of the carriers.

1. A method for producing a starting material for a silicon solar cell with passivated contacts, comprising:
providing a silicon wafer with a tunnel oxide layer
coating the tunnel oxide layer with at least one first layer of amorphous silicon by means of cathode sputtering;
coating the at least one first layer with at least one second layer comprising a dopant by means of cathode sputtering; and
annealing the coated silicon wafer at a temperature of at least 700° C.

2. The method according to claim 1, wherein the tunnel oxide layer comprises an SiO₂ layer having a thickness of 0.5 nm to 10 nm.

3. The method according to claim 1, wherein the at least one first layer consists of intrinsic silicon and/or doped silicon.

4. The method according to claim 1, wherein the at least one second layer comprises one or a combination of the following materials: silicon or silicon oxide doped with an element from the 3rd or 5th main group or an element from the 3rd or 5th main group as a pure substance or in the form of an oxide.

5. The method according to claim 4, wherein the proportion of the element from the 3rd or 5th main group is at least 0.5 mol % of the second layer.

6. The method according to claim 1, wherein the second layer has a thickness between 10 nm and 1 μm.

7. The method according to claim 1, wherein the provision of a silicon wafer with a tunnel oxide layer comprises wet-chemical generation of the tunnel oxide layer or generation of the tunnel oxide layer by a plasma process on the silicon wafer.

8. The method according to claim 1, wherein the at least one first layer and the at least one second layer are applied in a same cathode sputtering machine.

9. The method according to claim 1, wherein the annealing step causes that the at least one first layer of amorphous silicon is converted into a doped polycrystalline silicon layer.

10. The method according to claim 9, wherein a silicon layer doped with the dopant of the at least one second layer is formed directly below the tunnel oxide layer in the silicon wafer and wherein the dopant concentration drops across said silicon layer.

11. The method according to claim 10, wherein the silicon layer doped with the dopant of the second layer is formed in a region extending from the tunnel oxide layer to a maximum of 50 nm below the tunnel oxide layer.

12. The method according to claim 9, wherein the electrically active dopant concentration in the doped polycrystalline silicon layer is at least 1×10²⁰ cm⁻³ in the case of p-doping and at least 5×10¹⁹ cm⁻³ in the case of n-doping.

13. The method according to claim 1, further comprising:
coating the side of the silicon wafer opposite the tunnel oxide layer with at least one third layer comprising a dopant by means of cathode sputtering.

14. The method according to claim 13, wherein the third layer comprises one or a combination of the following materials: silicon or silicon oxide doped with an element from the 3rd or 5th main group, or an element from the 3rd or 5th main group as a pure substance or in the form of an oxide.

15. The method according to claim 13, wherein the annealing step causes that a silicon layer doped with the dopant of the third layer is formed below the third layer in the silicon wafer.

16. The method according to claim 1, wherein the silicon wafer is provided with a tunnel oxide layer on both sides and wherein the method comprises:
coating each of the two tunnel oxide layers with at least one first layer of amorphous silicon by means of cathode sputtering;
coating each of the two first layers with at least one second layer comprising a dopant by means of cathode sputtering.

17. The method according to claim 16, wherein the annealing step causes a simultaneous conversion of each of the at least one first layer of amorphous silicon on both sides into a doped polycrystalline silicon layer.

18. The method according to claim 17, wherein the annealing step causes the formation of a silicon layer doped with the dopant of the at least one second layer directly below and directly above the tunnel oxide layer and wherein the dopant concentration drops across said silicon layers.

19. The method according to claim 17, wherein the silicon layers doped with the dopant of the at least one second layer are formed in a region extending from the tunnel oxide layer to a maximum of 50 nm below and above the tunnel oxide layer.

20. The method according to claim 1, further comprising:
coating the at least one second layer with a hydrogen-enriched cover layer comprising a nitride and/or an oxide.

21. The method according to claim 1, wherein the silicon wafer is moved during the two coatings with the first and second layers as well as between the two coatings.

22. The method according to claim 1, wherein the provision of a silicon wafer with a tunnel oxide layer comprises coating the silicon wafer with the tunnel oxide layer by means of cathode sputtering.

23. The method according to claim 22, wherein the silicon wafer is moved during the two coatings with the first and second layers as well as during the coating with the tunnel oxide layer.

24. The method according to claim 1, wherein the production takes place in a continuous process.

25. A machine for producing a starting material for a silicon solar cell with passivated contacts, comprising:
a first cathode sputtering unit adapted to coat a substrate with at least one first layer of amorphous silicon;
a second cathode sputtering unit adapted to coat the first layer with at least one second layer comprising a dopant; and
optionally an annealing unit adapted to anneal the substrate coated with the first and second layers at a temperature of at least 700° C.;
wherein the first and second cathode sputtering devices are integrated in a common vacuum process section of the machine.

26. The machine according to claim 25, wherein the first and second cathode sputtering devices are spaced apart from each other along the process section.

27. The machine according to claim 26, wherein the distance between the outer sides of the cathodes of the first and second cathode sputtering devices is at least 10 cm.

28. The machine according to claim 25, further comprising an upstream wet-chemical unit adapted to provide a silicon wafer with a tunnel oxide layer by a wet-chemical process, or a plasma unit adapted to provide a silicon wafer with a tunnel oxide layer by a plasma process.

29. The machine according to claim 25, further comprising:
a further cathode sputtering unit adapted to coat the silicon wafer with a tunnel oxide layer; wherein the first, the second and the further cathode sputtering devices are integrated in a common vacuum process section of the machine.

30. The machine according to claim 25, further comprising:
a third cathode sputtering unit adapted to coat the substrate on the side opposite the first layer with at least one third layer comprising a dopant;
wherein the first, second and third cathode sputtering devices are integrated in a common vacuum process section of the machine.

31. The machine according to claim 25, further comprising:
a third cathode sputtering unit adapted to coat the substrate on the side opposite the first layer with at least one first layer of amorphous silicon; and
a fourth cathode sputtering unit adapted to coat the first layer with at least one second layer comprising a dopant;
wherein the first, second, third and fourth cathode sputtering devices are integrated in a common vacuum process section of the machine.
